(19) United States
(12) Patent Application Publication
(10) Pub. No.: US 2024/0348208 A1
(43) Pub. Date: Oct. 17, 2024

(54) POWER AMPLIFIER CIRCUIT AND RADIO FREQUENCY CIRCUIT

(71) Applicant: Murata Manufacturing Co., Ltd., Nagaokakyo-shi (JP)

(72) Inventors: Shinya HITOMI, Nagaokakyo-shi (JP); Satoshi TANAKA, Nagaokakyo-shi (JP); Hirotsugu MORI, Nagaokakyo-shi (JP)

(73) Assignee: Murata Manufacturing Co., Ltd., Nagaokakyo-shi (JP)

(21) Appl. No.: 18/752,959

(22) Filed: Jun. 25, 2024

Related U.S. Application Data
(63) Continuation of application No. PCT/JP2022/044466, filed on Dec. 1, 2022.

(30) Foreign Application Priority Data
Dec. 27, 2021 (JP) 2021-212365

(51) Int. Cl. H03F 1/02; H03F 3/24; H04B 1/04

(52) U.S. Cl. CPC H03F 1/0222; H03F 3/245; H04B 1/0475; H03F 2200/102; H03F 2200/105; H03F 2200/451; H04B 2001/0425

(57) ABSTRACT

A circuit includes a power amplifier configured to amplify a first signal in a first channel and a second signal in a second channel under a condition that the first signal and the second signal are simultaneously transmitted. An envelope tracking mode is applied to the power amplifier under a condition that a frequency gap between the first channel and the second channel is less than a first threshold width, and an average power tracking mode is applied to the power amplifier under a condition that the frequency gap is at least the first threshold width.

### CROSS-REFERENCE TO RELATED APPLICATIONS

This application is a continuation application of PCT International Application No. PCT/JP2022/044466 filed on Dec. 1, 2022, designating the United States of America, which is based on and claims priority to Japanese Patent Application No. 2021-212365 filed on Dec. 27, 2021. The entire disclosures of the above-identified applications, including the specifications, drawings, and claims are incorporated herein by reference in their entirety.

### BACKGROUND

With 5th Generation New Radio (5G NR), a wider frequency band than a conventional frequency band can be used, and efficient usage of such a wider frequency band has been examined. For example, technology for simultaneously transmitting a plurality of signals in a plurality of channels within a frequency band has been examined. One of such simultaneous transmission technologies is intra-band non-contiguous carrier aggregation for communication by simultaneously using a plurality of discontinuous component carriers.

For mobile communication devices such as mobile phones, a tracking mode for dynamically adjusting a power supply voltage applied to a power amplifier circuit has been increasingly used in order to improve power-added efficiency (PAE) of the power amplifier circuit. Improvements in PAE can be made by applying an envelope tracking mode to a power amplifier circuit.

### SUMMARY

A power amplifier circuit according to an aspect of the present disclosure includes a power amplifier configured to amplify a first signal in a first channel and a second signal in a second channel under a condition that the first signal and the second signal are simultaneously transmitted. An envelope tracking mode is applied to the power amplifier under a condition that a frequency gap between the first channel and the second channel is less than a first threshold width, and an average power tracking mode is applied to the power amplifier under a condition that the frequency gap is at least the first threshold width.

A radio frequency circuit according to an aspect of the present disclosure includes: a power amplifier circuit that includes a power amplifier configured to amplify a first signal in a first channel and a second signal in a second channel; and a tracking circuit configured to supply a power supply voltage to the power amplifier. Under a condition that the first signal and the second signal are simultaneously transmitted, (i) the tracking circuit is configured to supply the power supply voltage to the power amplifier in an envelope tracking mode, under a condition that a frequency gap between the first channel and the second channel is less than a first threshold width, (ii) the tracking circuit is configured to supply the power supply voltage to the power amplifier in an average power tracking mode, under a condition that the frequency gap is at least the first threshold width, and (iii) the power amplifier is configured to amplify the first signal and the second signal, by using the power supply voltage supplied from the tracking circuit.

A radio frequency circuit according to an aspect of the present disclosure includes: a power amplifier circuit that includes a power amplifier configured to amplify a first signal in a first channel and a second signal in a second channel; a tracking circuit that includes an envelope tracking circuit and an average tracking circuit; a radio frequency integrated circuit (RFIC) that supplies the first signal and the second signal; and a switch circuit connected between the power amplifier and the tracking circuit. The switch circuit switches the envelope tracking circuit and the average tracking circuit based on signal from the RFIC.

Benefits and advantages provided by the disclosed exemplary embodiments will be apparent from the disclosure and the drawings. The benefits and/or advantages may be obtained by various exemplary embodiments and features of the disclosure and the drawings, all of which are not necessarily provided in order to obtain one or more of the benefits and/or advantages.

### BRIEF DESCRIPTION OF DRAWINGS

FIG. 1A is a graph illustrating an example of a transition of a power supply voltage in an average power tracking mode.

FIG. 1B is a graph illustrating an example of a transition of a power supply voltage in an analog envelope tracking mode.

FIG. 1C is a graph illustrating an example of a transition of a power supply voltage in a digital envelope tracking mode.

FIG. 2 illustrates a circuit configuration of a communication device according to an exemplary embodiment.

FIG. 3 illustrates a relation between a frequency gap and tracking modes in the exemplary embodiment.

FIG. 4 illustrates transfer states of two channel signals with frequency gap G1.

FIG. 5 illustrates transfer states of two channel signals with frequency gap G2.

FIG. 6 illustrates transfer states of two channel signals with frequency gap G3.

FIG. 7 illustrates transfer states of two channel signals with frequency gap G4.

FIG. 8 illustrates a circuit configuration of a power amplifier circuit according to Variation 1 of the exemplary embodiment.

FIG. 9 illustrates a circuit configuration of the power amplifier circuit according to Variation 1 of the exemplary embodiment.

FIG. 10 illustrates a circuit configuration of a power amplifier circuit according to Variation 2 of the exemplary embodiment.

FIG. 11 illustrates a circuit configuration of the power amplifier circuit according to Variation 2 of the exemplary embodiment.

FIG. 12 illustrates a circuit configuration of a communication device according to another exemplary embodiment.

### DETAILED DESCRIPTION

As recognized by the present inventors, when an envelope tracking mode is applied to a power amplifier circuit in a case in which a plurality of signals is simultaneously transmitted using a plurality of channels in a wider communication band, quality of the signals may deteriorate.

In view of this, the present disclosure provides a power amplifier circuit and a radio frequency circuit that can improve PAE while reducing a decrease in signal quality in a case in which a plurality of signals is simultaneously transmitted using a plurality of channels.

The following describes in detail exemplary embodiments of the present disclosure, with reference to the drawings. Note that the exemplary embodiments described below each show a general or specific example. The numerical values, shapes, materials, elements, and the arrangement and connection of the elements, for instance, described in the following exemplary embodiments are mere examples, and thus are not intended to limit the present disclosure.

Note that the drawings are schematic diagrams to which emphasis, omission, and ratio adjustment are appropriately added in order to illustrate the present disclosure, and thus are not necessarily accurate illustrations. The drawings may show shapes, positional relations, and ratios that are different from actual shapes, actual positional relations, and actual ratios. In the drawings, the same numeral is given to substantially the same element, and redundant description may be omitted or simplified.

In the circuit configuration of the present disclosure, “being connected” includes not only the case of being directly connected by a connection terminal and/or a line conductor, but also the case of being electrically connected via another circuit element. “Being connected between A and B” means being connected between A and B and to both of A and B, and includes, in addition to a series connection to a path between A and B, parallel connection (shunt connection) between the path and ground.

First, a tracking mode applied to a power amplifier circuit in the exemplary embodiments below is to be described. The tracking mode is a mode for dynamically adjusting a power supply voltage that is applied to a power amplifier circuit. Although there are several types of tracking modes, an average power tracking (APT) mode and an envelope tracking (ET) mode (including an analog ET mode and a digital ET mode) are to be used in the exemplary embodiments below. Note that the tracking modes are not limited to those modes.

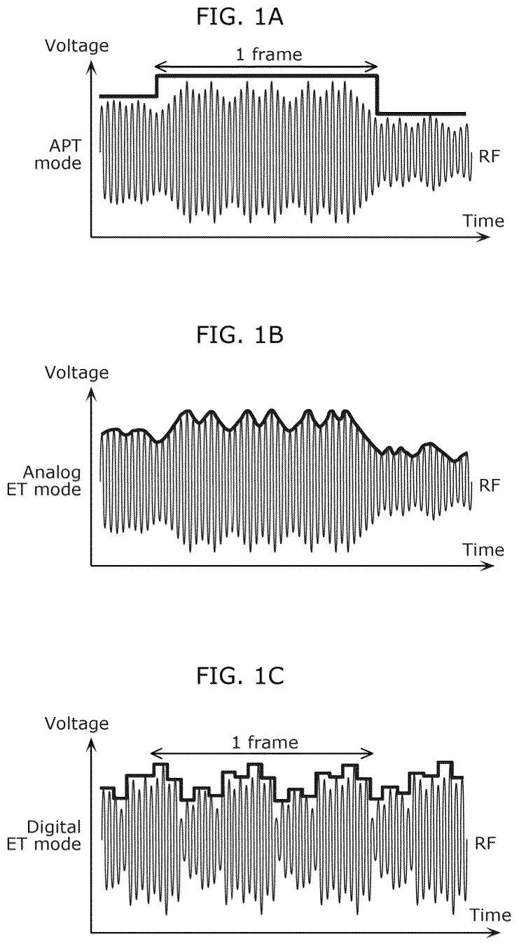

The APT mode, the analog ET mode, and the digital ET mode are to be described with reference to FIG. 1A to FIG. 1C. In each of FIG. 1A to FIG. 1C, the horizontal axis indicates time, whereas the vertical axis indicates voltage. Furthermore, the thick solid lines represent power supply voltages, and thin solid lines (in waveform) represent modulated waves.

FIG. 1A is a graph illustrating an example of a transition of a power supply voltage in the APT mode. In the APT mode, the power supply voltage is changed to a plurality of discrete voltage levels in single-frame units. As a result, a power supply voltage signal forms rectangular waves. In the APT mode, the voltage level of a power supply voltage is determined based on an average output power. Note that in the APT mode, the voltage level may change in units smaller than one frame (a sub-frame, for example).

A frame means a unit for forming a radio frequency signal (modulated waves). For example, in 5th Generation New Radio (5G NR) and in Long Term Evolution (LTE), a frame includes ten sub-frames, each sub-frame includes a plurality of slots, and each slot includes a plurality of symbols. The length of a sub-frame is 1 ms, and the length of a frame is 10 ms.

FIG. 1B is a graph illustrating an example of a transition of a power supply voltage in the analog ET mode. The analog ET mode is an example of the ET mode. In the analog ET mode, an envelope of modulated waves is tracked by continuously changing the power supply voltage, as illustrated in FIG. 1B. In the analog ET mode, the power supply voltage is determined based on an envelope signal.

An envelope signal indicates an envelope of modulated waves. An envelope value is represented by a square root of (I2+Q2), for example. Here, (I, Q) represents a constellation point. A constellation point represents a signal modulated by digital modulation on a constellation diagram. (I, Q) are determined by baseband integrated circuit (BBIC) 4, based on transmission information, for example.

FIG. 1C is a graph illustrating an example of a transition of a power supply voltage in the digital ET mode. The digital ET mode is an example of the ET mode. In the digital ET mode, an envelope of modulated waves is tracked by changing a power supply voltage to a plurality of discrete voltage levels in a single frame, as illustrated in FIG. 1C. As a result, a power supply voltage signal forms rectangular waves. In the digital ET mode, a power supply voltage level is selected or set from among a plurality of discrete voltage levels, based on an envelope signal.

### Exemplary Embodiment

An exemplary embodiment is to be described.

### 1.1 Circuit Configuration

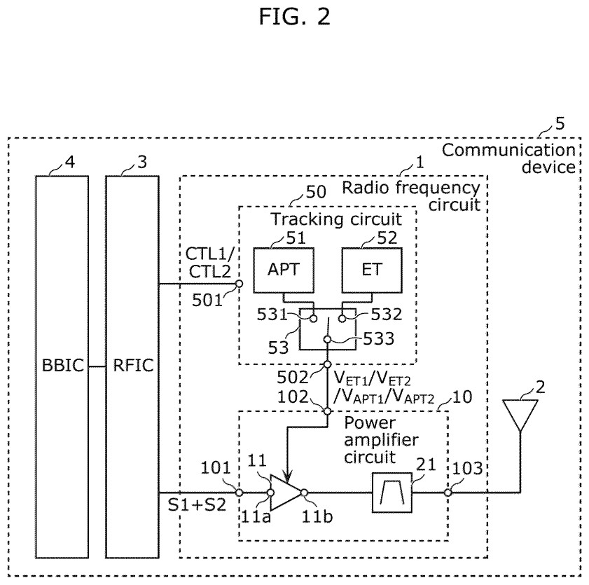

A circuit configuration of communication device 5, radio frequency circuit 1, power amplifier circuit 10, and tracking circuit 50 according to Exemplary Embodiment 1 is to be described with reference to FIG. 2. FIG. 2 illustrates a circuit configuration of communication device 5 according to the present exemplary embodiment.

### 1.1.1 Circuit Configuration of Communication Device 5

A circuit configuration of communication device 5 is to be described. As illustrated in FIG. 2, communication device 5 according to the present exemplary embodiment includes radio frequency circuit 1, antenna 2, radio frequency integrated circuit (RFIC) 3, and baseband integrated circuit (BBIC) 4.

Radio frequency circuit 1 transfers radio frequency signals between antenna 2 and RFIC 3. An internal configuration of radio frequency circuit 1 is to be described later.

Antenna 2 is connected to radio frequency circuit 1. Antenna 2 receives radio frequency signals from radio frequency circuit 1 and externally outputs the radio frequency signals.

RFIC 3 is an example of a signal processing circuit that processes radio frequency signals. Specifically, RFIC 3 processes, by up-conversion, for instance, transmission signals input by BBIC 4 and outputs radio frequency transmission signals generated by the processing to a transmission path of radio frequency circuit 1. RFIC 3 includes a controller that controls radio frequency circuit 1. Note that some or all of the functions as the controller of RFIC 3 may be implemented outside RFIC 3, and may be implemented in BBIC 4 or radio frequency circuit 1, for example.

BBIC 4 is a base band signal processing circuit that processes signals using an intermediate frequency band lower than a frequency of a radio frequency signal transferred by radio frequency circuit 1. Examples of signals processed by BBIC 4 include an image signal for displaying an image and/or an audio signal for generating sound through a loudspeaker.

Note that the circuit configuration of communication device 5 illustrated in FIG. 2 is an example, and the circuit configuration thereof is not limited thereto. For example, communication device 5 may not include antenna 2 and/or BBIC 4.

### 1.1.2 Circuit Configuration of Radio Frequency Circuit 1

Next, a circuit configuration of radio frequency circuit 1 is to be described. As illustrated in FIG. 2, radio frequency circuit 1 includes power amplifier circuit 10 and tracking circuit 50.

Power amplifier circuit 10 is connected to tracking circuit 50 and can receive supply of a power supply voltage from tracking circuit 50. A detailed circuit configuration of power amplifier circuit 10 is to be described later.

Tracking circuit 50 can supply a power supply voltage to power amplifier circuit 10. A detailed circuit configuration of tracking circuit 50 is to be described later.

### 1.1.3 Circuit Configuration of Power Amplifier Circuit 10

Next, a circuit configuration of power amplifier circuit 10 is to be described. As illustrated in FIG. 2, power amplifier circuit 10 includes power amplifier 11, filter 21, input terminal 101, power supply voltage terminal 102, and output terminal 103.

Input terminal 101 is a terminal for receiving radio frequency transmission signals from outside of radio frequency circuit 1. In the present exemplary embodiment, power amplifier circuit 10 can receive first signal S1 in a first channel and second signal S2 in a second channel through input terminal 101. Input terminal 101 is connected to RFIC 3 outside of radio frequency circuit 1.

First signal S1 and second signal S2 have different center frequencies. In the present exemplary embodiment, the first channel and the second channel are two channels included in the same band and used in intra-band non-contiguous carrier aggregation (CA). Note that the first channel and the second channel may be two channels used in intra-band contiguous CA. In this case, the first channel and the second channel have no frequency gap. Furthermore, the first channel and the second channel may be two channels included in different bands or may be used in inter-band non-contiguous CA. Moreover, the first channel and the second channel may be two channels used in E-UTRAN New Radio-Dual Connectivity (EN-DC).

Power supply voltage terminal 102 is a terminal for receiving a power supply voltage from tracking circuit 50. Power supply voltage terminal 102 is connected to output terminal 502 of tracking circuit 50 outside of power amplifier circuit 10.

Output terminal 103 is a terminal for supplying radio frequency transmission signals to the outside of radio frequency circuit 1. Output terminal 103 is connected to antenna 2 outside of radio frequency circuit 1.

Power amplifier 11 is connected between input terminal 101 and filter 21 and connected to power supply voltage terminal 102. Specifically, input terminal 11a of power amplifier 11 is connected to input terminal 101, and output terminal 11b of power amplifier 11 is connected to filter 21 and power supply voltage terminal 102. Power amplifier 11 can amplify first signal S1 and second signal S2 by using a power supply voltage supplied through power supply voltage terminal 102. Specifically, power amplifier 11 can amplify a signal resulting from combining first signal S1 and second signal S2. Thus, power amplifier 11 can simultaneously amplify first signal S1 and second signal S2. Note that power amplifier 11 can amplify only one of first signal S1 or second signal S2.

Filter 21 is connected between power amplifier 11 and output terminal 103. Specifically, one end of filter 21 is connected to output terminal 11b of power amplifier 11, and another end of filter 21 is connected to output terminal 103. Filter 21 is a band-pass filter (BPF) having a passband that includes band A. Filter 21 may be embodied using any of a surface acoustic wave (SAW) filter, a bulk acoustic wave (BAW) filter, an LC resonant filter, or a dielectric resonant filter, but is not limited thereto.

Band A is a frequency band for a communication system established using a radio access technology (RAT). Band A is defined in advance by, for instance, a standardizing body (such as the 3rd Generation Partnership Project (3GPP (registered trademark)) or the Institute of Electrical and Electronics Engineers (IEEE), for example). Examples of such a communication system include a 5th Generation New Radio (5G NR) system, a Long Term Evolution (LTE) system, and a wireless local area network (WLAN) system, for instance.

In the present exemplary embodiment, n77 for 5G NR is used as band A. Note that band A is not limited to n77. For example, band A may be n78 or n79 for 5G NR or may be Band 42 for LTE. Furthermore, band A may be a licensed band or an unlicensed band within a range of 5 GHz to 7.125 GHZ.

Note that the circuit configuration of power amplifier circuit 10 illustrated in FIG. 2 is an example, and the circuit configuration thereof is not limited thereto. For example, power amplifier circuit 10 may include an impedance matching circuit connected between arbitrary two circuit elements (such as power amplifier 11 and filter 21, for example). The impedance matching circuit can be provided, including an inductor and/or a capacitor, for example. In addition, power amplifier circuit 10 may not include filter 21, for example.

### 1.1.4 Circuit Configuration of Tracking Circuit 50

Next, a circuit configuration of tracking circuit 50 is to be described. As illustrated in FIG. 2, tracking circuit 50 includes average power tracker (APT) 51, envelope tracker (ET) 52, switch circuit 53, control terminal 501, and output terminal 502.

Control terminal 501 is a terminal for receiving control signals from outside of radio frequency circuit 1. Control terminal 501 is connected to RFIC 3 outside of radio frequency circuit 1.

Output terminal 502 is a terminal for supplying a power supply voltage to power amplifier circuit 10. Output terminal 502 is connected to power supply voltage terminal 102 of power amplifier circuit 10 outside of tracking circuit 50.

APT 51 can supply power supply voltage V_{APT1} in a first APT mode, and supply power supply voltage V_{APT2} in a second APT mode. Specifically, in a case in which first signal S1 in the first channel and second signal S2 in the second channel are simultaneously transmitted, under a condition that a frequency gap between the first channel and the second channel is at least a first threshold width W_{TH1} and less than a third threshold width W_{TH3}, APT 51 can supply power supply voltage V_{APT1} in the first APT mode. Further, in a case in which first signal S1 in the first channel and second signal S2 in the second channel are simultaneously transmitted, under a condition that a frequency gap between the first channel and the second channel is at least the third threshold width W_{TH3}, APT 51 can supply power supply voltage V_{APT2} in the second APT mode. At this time, power supply voltage V_{APT2} supplied in the second APT mode is higher than power supply voltage V_{APT1} supplied in the first APT mode. Thus, for the same average power, power supply voltage V_{APT2} is higher than power supply voltage V_{APT1}.

ET 52 can supply power supply voltage V_{ET1} in a first ET mode, and supply power supply voltage V_{ET2} in a second ET mode. Specifically, in a case in which first signal S1 in the first channel and second signal S2 in the second channel are simultaneously transmitted, under a condition that a frequency gap between the first channel and the second channel is less than a second threshold width W_{TH2}, ET 52 can supply power supply voltage V_{ET1} in the first ET mode. Further, in a case in which first signal S1 in the first channel and second signal S2 in the second channel are simultaneously transmitted, under a condition that a frequency gap between the first channel and the second channel is at least the second threshold width W_{TH2} and less than first threshold width W_{TH1}, ET 52 can supply power supply voltage V_{ET2} in the second ET mode. At this time, power supply voltage V_{ET2} supplied in the second ET mode is higher than power supply voltage V_{ET1} supplied in the first ET mode. Thus, for an envelope signal showing the same value, power supply voltage V_{ET2} is higher than power supply voltage V_{ET1}. Stated differently, in the second ET mode, a higher power supply voltage is supplied to make a gain compression smaller than the gain compression in the first ET mode. Specifically, in the first ET mode, power supply voltage V_{ET1} is supplied to obtain an output power that is compressed by, for example, 2 dB for an input power corresponding to an envelope signal, whereas power supply voltage V_{ET2} is supplied to obtain an output power that is compressed by, for example, 0.5 dB to 1 dB for an input power corresponding to an envelope signal.

As a first threshold width W_{TH1}, a second threshold width W_{TH2}, and a third threshold width W_{TH3}, values that are empirically and/or experimentally determined in advance according to, for instance, a performance requirement of communication device 5, and thus are not limited in particular.

Either an analog ET mode or a digital ET mode may be used for each of the first ET mode and the second ET mode. Thus, ET 52 may be either one of an analog envelope tracker or a digital envelope tracker.

Switch circuit 53 is connected between (i) power amplifier 11 and (ii) APT 51 and ET 52. Specifically, switch circuit 53 includes terminal 531 connected to APT 51, terminal 532 connected to ET 52, and terminal 533 connected to output terminal 502. Switch circuit 53 includes a single-pole double-throw (SPDT) switch circuit, for example.

With this connection configuration, switch circuit 53 can connect terminal 531 or 532 to terminal 533, based on a control signal from RFIC 3. Specifically, in a case in which a frequency gap between the first channel and the second channel is at least a first threshold width W_{TH1}, switch circuit 53 can connect APT 51 to output terminal 502 without connecting ET 52 to output terminal 502. On the other hand, in a case in which a frequency gap between the first channel and the second channel is less than the first threshold width W_{TH1}, switch circuit 53 can connect ET 52 to output terminal 502 without connecting APT 51 to output terminal 502.

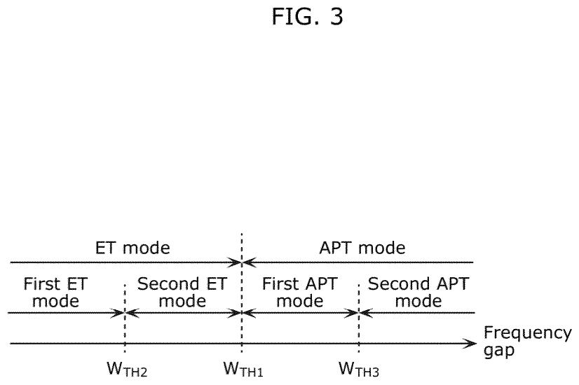

As described above, tracking circuit 50 can selectively apply the first ET mode, the second ET mode, the first APT mode, and the second APT mode to power amplifier 11, according to a frequency gap between the first channel and the second channel, as illustrated in FIG. 3.

Note that the circuit configuration of tracking circuit 50 illustrated in FIG. 2 is an example, and the circuit configuration thereof is not limited thereto. For example, switch circuit 53 may not be included in tracking circuit 50, and may be included in power amplifier circuit 10. For example, tracking circuit 50 may include a multimode tracker, instead of APT 51, ET 52, and switch circuit 53. The multimode tracker can selectively supply a power supply voltage in the ET mode and a power supply voltage in the APT mode. Although an internal configuration of the multimode tracker is not limited in particular, the multimode tracker includes a direct current (DC) to DC converter that is used in both the APT mode and the ET mode, for example, and a modulator used in the ET mode.

### 1.2 Transfer States of Two Channel Signals with Frequency Gaps

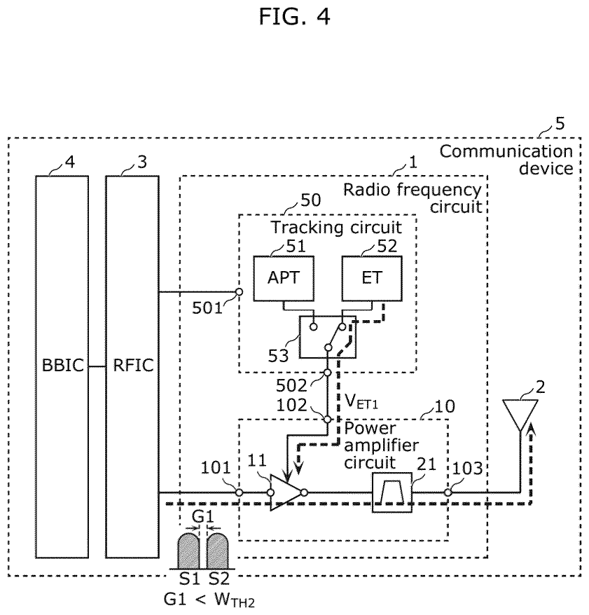

Next, in communication device 5 according to the present exemplary embodiment, transfer states of two channel signals with frequency gaps are to be described with reference to FIG. 4 to FIG. 7. FIG. 4 to FIG. 7 each illustrate transfer states of two channel signals with frequency gaps G1 to G4.

In FIG. 4, RFIC 3 supplies first signal S1 in the first channel and second signal S2 in the second channel under a condition that frequency gap G1 between the first channel and the second channel is less than a second threshold width W_{TH2}. Thus, switch circuit 53 connects ET 52 to output terminal 502, and ET 52 supplies power supply voltage V_{ET1} in the first ET mode. Accordingly, power amplifier 11 can amplify first signal S1 and second signal S2, using power supply voltage V_{ET1} supplied from ET 52. Amplified first signal S1 and amplified second signal S2 pass through filter 21 and are transferred to antenna 2 through output terminal 103. Accordingly, first signal S1 and second signal S2 are transmitted from communication device 5.

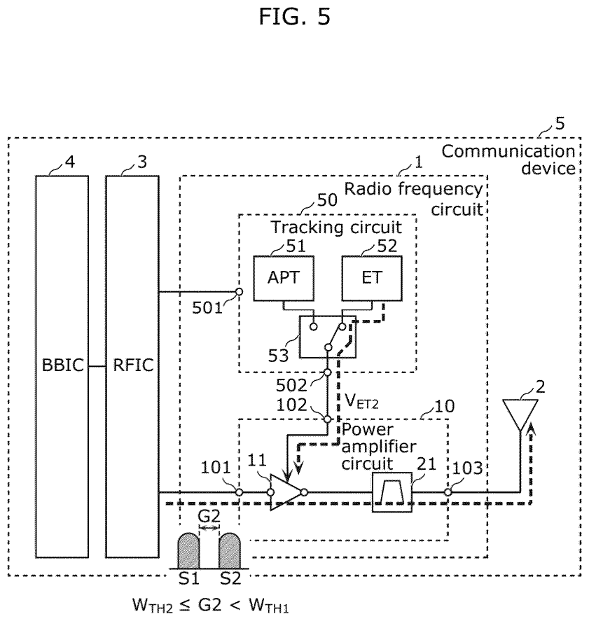

In FIG. 5, RFIC 3 supplies first signal S1 in the first channel and second signal S2 in the second channel under a condition that frequency gap G2 between the first channel and the second channel is at least a second threshold width W_{TH2} and less than the first threshold width W_{TH1}. Thus, switch circuit 53 connects ET 52 to output terminal 502, and ET 52 supplies power supply voltage V_{ET2} in the second ET mode. Accordingly, power amplifier 11 can amplify first signal S1 and second signal S2, using power supply voltage V_{ET2} supplied from ET 52. Amplified first signal S1 and amplified second signal S2 pass through filter 21 and are transferred to antenna 2 through output terminal 103. Accordingly, first signal S1 and second signal S2 are transmitted from communication device 5.

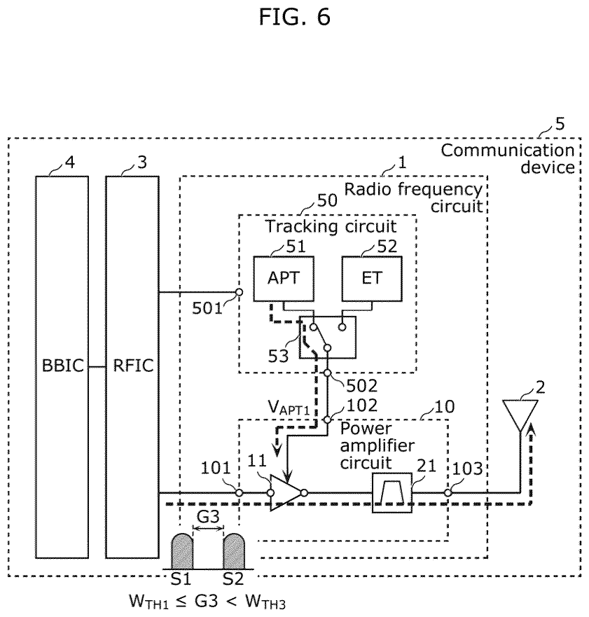

In FIG. 6, RFIC 3 supplies first signal S1 in the first channel and second signal S2 in the second channel under a condition that frequency gap G3 between the first channel and the second channel is at least the first threshold width W_{TH1} and less than a third threshold width W_{TH3}. Thus, switch circuit 53 connects APT 51 to output terminal 502, and APT 51 supplies power supply voltage V_{APT1} in the first APT mode. Accordingly, power amplifier 11 can amplify first signal S1 and second signal S2, using power supply voltage V_{APT1} supplied from APT 51. Amplified first signal S1 and amplified second signal S2 pass through filter 21 and are transferred to antenna 2 through output terminal 103. Accordingly, first signal S1 and second signal S2 are transmitted from communication device 5.

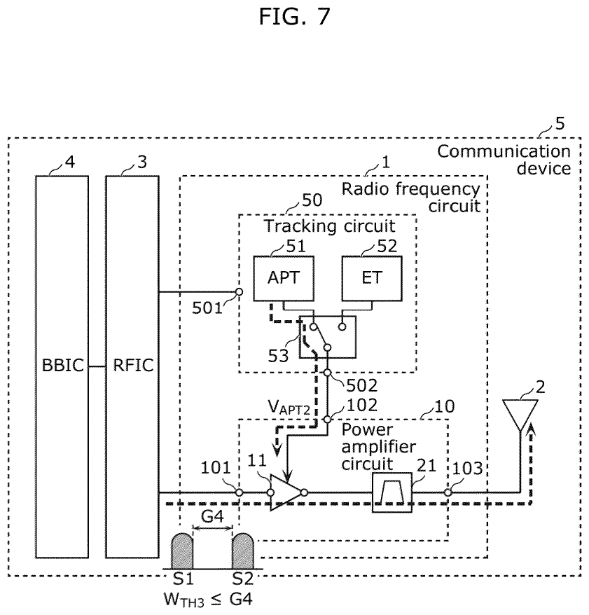

In FIG. 7, RFIC 3 supplies first signal S1 in the first channel and second signal S2 in the second channel under a condition that frequency gap G4 between the first channel and the second channel is at least the third threshold width W_{TH3}. Thus, switch circuit 53 connects APT 51 to output terminal 502, and APT 51 supplies power supply voltage V_{APT2} in the second APT mode. Accordingly, power amplifier 11 can amplify first signal S1 and second signal S2, using power supply voltage V_{APT2} supplied from APT 51. Amplified first signal S1 and amplified second signal S2 pass through filter 21 and are transferred to antenna 2 through output terminal 103. Accordingly, first signal S1 and second signal S2 are transmitted from communication device 5.

Note that a relation between a frequency gap and a power supply voltage in communication device 5 can be identified by monitoring a power supply voltage supplied to power amplifier 11 using a wireless communication tester in a case in which communication device 5 simultaneously transmits signals in two channels while channels having different frequency gaps are combined.

Note that in the present exemplary embodiment, the case in which first signal S1 in the first channel and second signal S2 in the second channel are simultaneously transmitted, radio frequency circuit 1 can transmit only one of first signal S1 in the first channel or second signal S2 in the second channel. In a case in which only one of first signal S1 in the first channel or second signal S2 in the second channel is transmitted, tracking circuit 50 can improve power-added efficiency (PAE) by supplying a power supply voltage in the ET mode (the first ET more or the second ET mode) to power amplifier circuit 10.

### 1.3 Effects and Others

As described above, power amplifier circuit 10 according to the present exemplary embodiment includes power amplifier 11 configured to amplify first signal S1 in a first channel and second signal S2 in a second channel under a condition that first signal S1 and second signal S2 are simultaneously transmitted. An ET mode is applied to power amplifier 11 under a condition that a frequency gap between the first channel and the second channel is less than a first threshold width W_{TH1}, and an APT mode is applied to power amplifier 11 under a condition that the frequency gap is at least the first threshold width W_{TH1}.

The greater the frequency gap between the first channel and the second channel is, the more a bandwidth of the first signal and the second signal as a whole increases. Accordingly, it is difficult for envelope signals of the first signal and the second signal to track the power supply voltage in the ET mode, and distortion of signals amplified by power amplifier 11 increases. Thus, in a case in which the frequency gap is relatively large, distortion of signals can be made less by applying the APT mode to power amplifier 11 than the distortion under a condition that the ET mode is applied to power amplifier 11. On the other hand, in a case in which the frequency gap is relatively small, PAE can be made higher by applying the ET mode to power amplifier 11 than the PAE under a condition that the APT mode is applied to power amplifier 11. Thus, power amplifier circuit 10 can improve PAE while reducing a decrease in signal quality in a case in which a plurality of signals is simultaneously transmitted using a plurality of channels.

For example, in power amplifier circuit 10 according to the present exemplary embodiment, a second ET mode may be applied to power amplifier 11 under a condition that the frequency gap is at least a second threshold width W_{TH2} and less than the first threshold width W_{TH1} and a first ET mode may be applied to power amplifier 11 under a condition that the frequency gap is less than the second threshold width W_{TH2}. Power supply voltage V_{ET2} supplied in the second ET mode may be higher than power supply voltage V_{ET1} supplied in the first ET mode.

According to this, under a condition that the ET mode is applied to power amplifier 11, the greater the frequency gap is, the higher the supplied power supply voltage is. Thus, in a state in which the peak power increases with an increase in the band width of the first signal and the second signal as a whole, a higher power supply voltage is supplied to power amplifier 11, and thus the linearity of power amplifier 11 for a higher output power can be improved so that the distortion of signals can be reduced.

For example, in power amplifier circuit 10 according to the present exemplary embodiment, a first APT mode may be applied to power amplifier 11 under a condition that the frequency gap is at least the first threshold width W_{TH1} and less than a third threshold width W_{TH3} and a second APT mode may be applied to power amplifier 11 under a condition that the frequency gap is at least the third threshold width W_{TH3}. Power supply voltage V_{APT2} supplied in the second APT mode may be higher than power supply voltage V_{APT1} supplied in the first APT mode.

According to this, under a condition that the APT mode is applied to power amplifier 11, the greater the frequency gap is, the higher the supplied power supply voltage is. Thus, in a state in which the peak power increases with an increase in the band width of the first signal and the second signal as a whole, a higher power supply voltage is supplied to power amplifier 11, and thus the linearity of power amplifier 11 for a higher output power can be improved so that the distortion of signals can be reduced.

For example, in power amplifier circuit 10 according to the present exemplary embodiment, the first channel and the second channel may be included in same band A. For example, in power amplifier circuit 10 according to the present exemplary embodiment, intra-band contiguous CA may be supported in band A.

According to this, PAE can be improved while reducing a decrease in signal quality in a case in which a plurality of signals is simultaneously transmitted using a plurality of channels in the same band. In particular, power amplifier circuit 10 can be effectively applied to a wider band.

For example, the ET mode may be applied to power amplifier 11 under a condition that one of the first signal or the second signal is transmitted.

According to this, under a condition that the channel band width of a signal amplified by power amplifier 11 is narrow, the ET mode can be used and PAE can be enhanced.

As described above, radio frequency circuit 1 according to the present exemplary embodiment includes: power amplifier circuit 10 that includes power amplifier 11 configured to amplify first signal S1 in a first channel and second signal S2 in a second channel; and tracking circuit 50 configured to supply a power supply voltage to power amplifier 11. Under a condition that first signal S1 and second signal S2 are simultaneously transmitted, (i) tracking circuit 50 is configured to supply the power supply voltage to power amplifier 11 in an ET mode, under a condition that a frequency gap between the first channel and the second channel is less than a first threshold width W_{TH1}, (ii) tracking circuit 50 is configured to supply the power supply voltage to power amplifier 11 in an APT mode, under a condition that the frequency gap between the first channel and the second channel is at the least first threshold width W_{TH1}, and (iii) power amplifier 11 is configured to amplify first signal S1 and second signal S2, by using the power supply voltage supplied from tracking circuit 50.

The greater the frequency gap between the first channel and the second channel is, the more a bandwidth of the first signal and the second signal as a whole increases. Accordingly, it is difficult for envelope signals of the first signal and the second signal to track the power supply voltage in the ET mode, and distortion of signals amplified by power amplifier 11 increases. Thus, in a case in which the frequency gap is relatively large, distortion of signals can be made less by supplying the power supply voltage to power amplifier 11 in the APT mode than the distortion under a condition that the power supply voltage is supplied to power amplifier 11 in the ET mode. On the other hand, in a case in which the frequency gap is relatively small, PAE can be made higher by supplying the power supply voltage to power amplifier 11 in the ET mode than the PAE under a condition that the power supply voltage is supplied to power amplifier 11 in the APT mode. Thus, power amplifier circuit 10 can improve PAE while reducing a decrease in signal quality in a case in which a plurality of signals is simultaneously transmitted using a plurality of channels.

For example, in radio frequency circuit 1 according to the present exemplary embodiment, in (i), tracking circuit 50 may be configured to: supply power supply voltage V_{ET2} to power amplifier 11 in a second ET mode, under a condition that the frequency gap is at least a second threshold width W_{TH2} and less than the first threshold width W_{TH1}; and supply power supply voltage V_{ET1} to power amplifier 11 in a first ET mode, under a condition that the frequency gap is less than the second threshold width W_{TH2}. Power supply voltage V_{ET2} supplied in the second ET mode may be higher than power supply voltage V_{ET1} supplied in the first ET mode.

According to this, under a condition that a power supply voltage is supplied to power amplifier 11 in the ET mode, the greater the frequency gap is, the higher the supplied power supply voltage is. Thus, in a state in which the peak power increases with an increase in the band width of the first signal and the second signal as a whole, a higher power supply voltage is supplied to power amplifier 11, and thus the linearity of power amplifier 11 with a higher output power can be improved so that the distortion of signals can be reduced.

For example, in radio frequency circuit 1 according to the present exemplary embodiment, in (ii), tracking circuit 50 may be configured to: supply power supply voltage V_{APT1} to power amplifier 11 in a first APT mode, under a condition that the frequency gap is at least the first threshold width W_{TH1} and less than a third threshold width W_{TH3}; and supply power supply voltage V_{APT2} to power amplifier 11 in a second APT mode, under a condition that the frequency gap is at least the third threshold width W_{TH3}. Power supply voltage V_{APT2} supplied in the second APT mode may be higher than power supply voltage V_{APT1} supplied in the first APT mode.

According to this, under a condition that the power supply voltage is supplied to power amplifier 11 in the APT mode, the greater the frequency gap is, the higher the supplied power supply voltage is. Thus, in a state in which the peak power increases with an increase in the band width of the first signal and the second signal as a whole, a higher power supply voltage is supplied to power amplifier 11, and thus the linearity of power amplifier 11 with a higher output power can be improved so that the distortion of signals can be reduced.

For example, in radio frequency circuit 1 according to the present exemplary embodiment, the first channel and the second channel may be included in same band A. For example, in power amplifier circuit 1 according to the present exemplary embodiment, intra-band contiguous CA may be supported in band A.

According to this, PAE can be improved while reducing a decrease in signal quality in a case in which a plurality of signals are simultaneously transmitted using a plurality of channels in the same band. In particular, radio frequency circuit 1 can be effectively used with a wider band.

For example, the ET mode may be applied to power amplifier 11 under a condition that one of the first signal or the second signal is transmitted.

According to this, under a condition that the channel band width of a signal amplified by power amplifier 11 is narrow, the ET mode can be used and PAE can be improved.

### Variation 1

Next, Variation 1 is to be described. This variation is different from the exemplary embodiment above mainly in that a variable notch filter is included in a power amplifier circuit. In the following, this variation is described, focusing on differences from the above exemplary embodiment, with reference to the drawings.

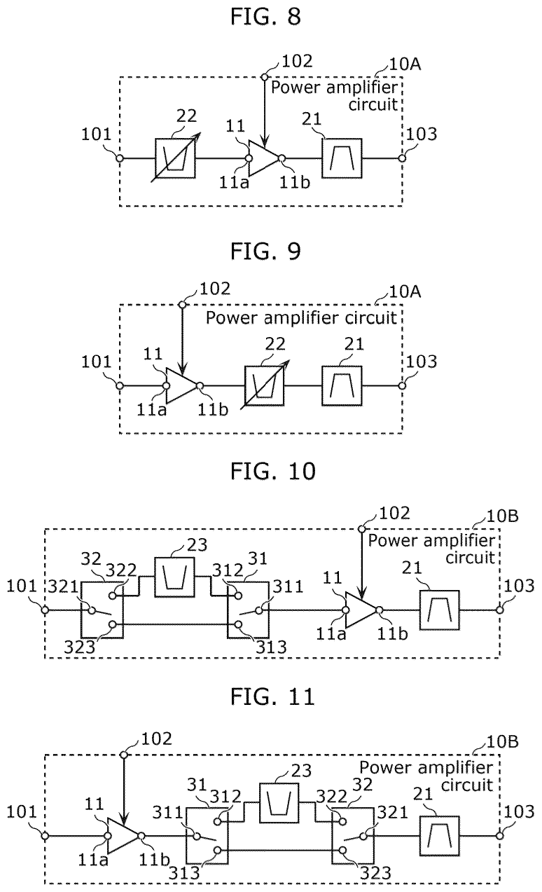

FIG. 8 illustrates a circuit configuration of power amplifier circuit 10A according to this variation. Power amplifier circuit 10A includes notch filter 22 in addition to power amplifier 11, filter 21, input terminal 101, power supply voltage terminal 102, and output terminal 103.

Notch filter 22 is an example of a band-elimination filter (BEF), is connected to power amplifier 11, and has an attenuation band that includes a frequency gap between the first channel and the second channel. In FIG. 8, notch filter 22 is a variable notch filter having a variable attenuation band and is connected to input terminal 11a of power amplifier 11. The attenuation band of notch filter 22 can be changed according to a frequency gap between first signal S1 and second signal S2.

Notch filter 22 may be embodied including any of a SAW filter, a BAW filter, an LC resonance filter, or a dielectric resonance filter, but is not limited thereto.

As described above, in radio frequency circuit 1 according to this variation, power amplifier circuit 10A may further include notch filter 22 connected to power amplifier 11, notch filter 22 having an attenuation band that includes the frequency gap between the first channel and the second channel.

According to this, notch filter 22 can attenuate noise included in the frequency gap between the first channel and the second channel, and signal quality can be improved.

For example, in radio frequency circuit 1 and power amplifier circuit 10A according to this variation, notch filter 22 may be a variable notch filter having a variable attenuation band.

According to this, notch filter 22 can attenuate noise included in different frequency gaps. Thus, signal quality can be improved for different combinations with regard to the first signal and the second signal, and versatility of radio frequency circuit 1 and power amplifier circuit 10A can be improved.

Note that in FIG. 8, notch filter 22 is connected to input terminal 11a of power amplifier 11, but is not limited to be connected thereto. For example, as illustrated in FIG. 9, notch filter 22 may be connected to output terminal 11b of power amplifier 11.

### Variation 2

Next, Variation 2 is to be described. This variation is different from the exemplary embodiment above mainly in that a switch circuit is connected between a power amplifier and a notch filter. In the following, this variation is described, focusing on differences from the above exemplary embodiment, with reference to the drawings.

FIG. 10 illustrates a circuit configuration of power amplifier circuit 10B according to this variation. Power amplifier circuit 10B includes notch filter 23 and switch circuits 31 and 32 in addition to power amplifier 11, filter 21, input terminal 101, power supply voltage terminal 102, and output terminal 103.

Notch filter 23 is an example of a band-elimination filter (BEF), is connected to power amplifier 11, and has an attenuation band that includes a frequency gap between the first channel and the second channel. In this variation, notch filter 23 is connected to input terminal 11a of power amplifier 11 via switch circuit 31.

Switch circuit 31 is connected between power amplifier 11 and notch filter 23. Switch circuit 31 includes terminal 311 connected to input terminal 11a of power amplifier 11, terminal 312 connected to notch filter 23, and terminal 313 connected to switch circuit 32. Switch circuit 31 includes an SPDT switch circuit, for example.

Switch circuit 32 is connected between notch filter 23 and input terminal 101. Switch circuit 32 includes terminal 321 connected to input terminal 101, terminal 322 connected to notch filter 23, and terminal 323 connected to terminal 313 of switch circuit 31. Switch circuit 32 includes an SPDT switch circuit, for example. Note that switch circuit 32 is an optional circuit element and may be omitted.

With such a connection configuration, switch circuits 31 and 32 can switch between connection of input terminal 101 to power amplifier 11 via notch filter 23 and connection of input terminal 101 to power amplifier 11 not via notch filter 23. Specifically, input terminal 101 is connected to power amplifier 11 via notch filter 23 by terminal 311 of switch circuit 31 being connected to terminal 312 and terminal 321 of switch circuit 32 being connected to terminal 322. On the other hand, input terminal 101 is connected to power amplifier 11 not via notch filter 23 by terminal 311 of switch circuit 31 being connected to terminal 313 and terminal 321 of switch circuit 32 being connected to terminal 323.

As described above, in radio frequency circuit 1 according to this variation, power amplifier circuit 10B may further include notch filter 23 connected to power amplifier 11, notch filter 23 having an attenuation band that includes the frequency gap between the first channel and the second channel.

According to this, notch filter 23 can attenuate noise included in the frequency gap between the first channel and the second channel, and signal quality can be improved.

For example, in radio frequency circuit 1 according to this variation, power amplifier circuit 10B may further include switch circuit 31 connected between power amplifier 11 and notch filter 23.

Accordingly, switch circuit 31 switches between connection and disconnection between power amplifier 11 and notch filter 23, and thus use and non-use of notch filter 23 can be switched according to a frequency gap. Thus, signal quality can be improved in simultaneous transmission of signals in two channels having a particular frequency gap. Furthermore, notch filter 23 can be prevented from giving harmful effect in simultaneous transmission of signals in two channels having a frequency gap different from a particular frequency gap.

Note that in FIG. 10, notch filter 23 is connected to input terminal 11a of power amplifier 11 via switch circuit 31, but is not limited to be connected thereto. For example, as illustrated in FIG. 11, notch filter 23 may be connected to output terminal 11b of power amplifier 11 via switch circuit 31. In this case, switch circuits 31 and 32 can switch between connection of power amplifier 11 to filter 21 via notch filter 23 and connection of power amplifier 11 to filter 21 not via notch filter 23.

### Other Exemplary Embodiments

The above has described the radio frequency circuit and the communication device according to the present disclosure, based on the exemplary embodiment, but the radio frequency circuit and the communication device according to the present disclosure are not limited to the above exemplary embodiment or the variations thereof. The present disclosure also encompasses another exemplary embodiment achieved by combining arbitrary elements in the above exemplary embodiments and variations thereof, variations resulting from applying, to the exemplary embodiments, various modifications that may be conceived by those skilled in the art within a range that does not depart from the scope of the present disclosure, and various devices that each include the radio frequency circuit described above.

For example, in circuit configurations of the radio frequency circuits and the communication devices according to the above exemplary embodiment and variations thereof, another circuit element and another line, for instance, may be provided between circuit elements and paths connecting signal paths, which are disclosed in the drawings. For example, a matching circuit may be provided between a power amplifier and a filter.

In the above exemplary embodiment, the communication device is a transmission device, but may be a transmitter-receiver device. In this case, the radio frequency circuit may include a low-noise amplifier circuit.

Note that in the above exemplary embodiment, the four tracking modes are selectively applied to power amplifier 11, but the number and types of the tracking modes are not limited to the ones in the above exemplary embodiment. For example, the first ET mode and the second ET mode may be selectively applied to power amplifier 11, and the first APT mode and the second APT mode may not be applied to power amplifier 11. In this case, tracking circuit 50 may not include APT 51 or switch circuit 53. For example, the first APT mode and the second APT mode may be selectively applied to power amplifier 11, and the first ET mode and the second ET mode may not be applied to power amplifier 11. In this case, tracking circuit 50 may not include ET 52 or switch circuit 53.

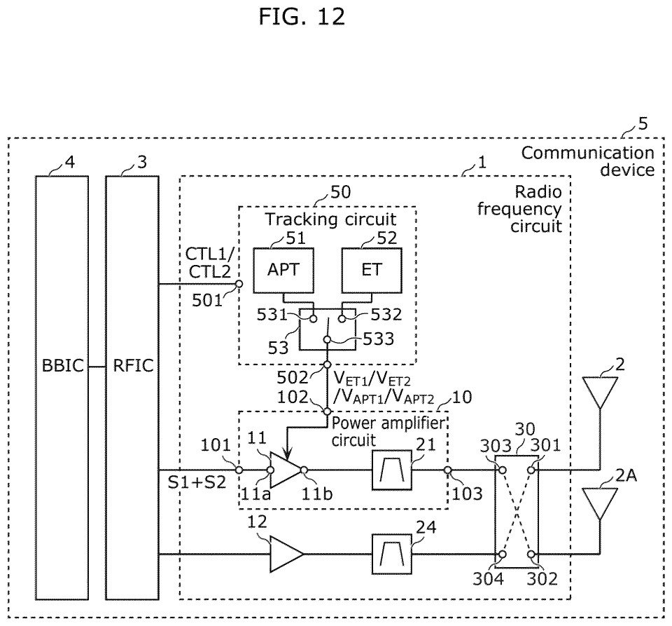

Note that in the above exemplary embodiment, radio frequency circuit 1 includes just one transmission path, but may include a plurality of transmission paths. For example, as illustrated in FIG. 12, communication device 5 may further include antenna 2A. At this time, radio frequency circuit 1 may further include power amplifier 12, filter 24, and switch circuit 30.

Power amplifier 12 is connected between RFIC 3 and filter 24, and can amplify transmission signals in band B. Note that a power supply voltage supplied to power amplifier 12 is not limited in particular, and may be a power supply voltage based on the ET mode, for example, or may be any power supply voltage. Thus, a path for supplying a power supply voltage to power amplifier 12 is omitted in FIG. 12.

Band B is a frequency band for a communication system established using radio access technology (RAT), similarly to band A. Bands A and B are a combination of bands with which simultaneous transmission is possible. For example, bands A and B are a combination of bands for carrier aggregation (CA). Further, bands A and B may be a combination of bands for E-UTRAN New Radio-Dual Connectivity (EN-DC) or New Radio-Dual Connectivity (NR-DC), for example.

As Band B, for example, one of the following LTE bands can be used, such as Band 1, Band 2, Band 3, Band 4, Band 13, Band 20, Band 26, Band 28, Band 66, and Band 71. Note that Band B is not limited thereto, and various bands defined by 3GPP, for instance, can be used as Band B.

Filter 24 is connected between power amplifier 12 and switch circuit 30. Specifically, one end of filter 24 is connected to an output end of power amplifier 12, and another end of filter 24 is connected to terminal 304 of switch circuit 30. Filter 24 has a passband that includes band B. Filter 24 may be embodied including any of a SAW filter, a BAW filter, an LC resonance filter, or a dielectric resonance filter, but is not limited thereto.

Switch circuit 30 is connected between antennas 2 and 2A and filters 21 and 24. Switch circuit 30 includes terminal 301 connected to antenna 2, terminal 302 connected to antenna 2A, terminal 303 connected to output terminal 103 of power amplifier circuit 10, and terminal 304 connected to filter 24.

With this connection configuration, switch circuit 30 can exclusively connect terminal 301 to terminal 303 or 304 and can exclusively connect terminal 302 to terminal 303 or 304, based on a control signal from RFIC 3, for example. Thus, switch circuit 30 can connect terminal 301 to one of terminal 303 or 304 and can connect terminal 302 to the remaining one of terminal 303 or 304.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The present disclosure is widely applicable to communication devices such as mobile phones as a radio frequency circuit disposed at a front end portion.

1. A power amplifier circuit comprising:
a power amplifier configured to amplify a first signal in a first channel and a second signal in a second channel under a condition that the first signal and the second signal are simultaneously transmitted, wherein
an envelope tracking mode is applied to the power amplifier under a condition that a frequency gap between the first channel and the second channel is less than a first threshold width, and
an average power tracking mode is applied to the power amplifier under a condition that the frequency gap is at least the first threshold width.

2. The power amplifier circuit according to claim 1, wherein
a second envelope tracking mode is applied to the power amplifier under a condition that the frequency gap is at least a second threshold width and less than the first threshold width,
a first envelope tracking mode is applied to the power amplifier under a condition that the frequency gap is less than the second threshold width, and
a power supply voltage supplied in the second envelope tracking mode is higher than a power supply voltage supplied in the first envelope tracking mode.

3. The power amplifier circuit according to claim 1, wherein
a first average power tracking mode is applied to the power amplifier under a condition that the frequency gap is at least the first threshold width and less than a third threshold width,
a second average power tracking mode is applied to the power amplifier under a condition that the frequency gap is at least the third threshold width, and
a power supply voltage supplied in the second average power tracking mode is higher than a power supply voltage supplied in the first average power tracking mode.

4. The power amplifier circuit according to claim 1, further comprising:
a band-elimination filter connected to the power amplifier, the band-elimination filter having an attenuation band that includes the frequency gap.

5. The power amplifier circuit according to claim 4, wherein the attenuation band of the band-elimination filter is variable.

6. The power amplifier circuit according to claim 4, further comprising:
a switch circuit connected between the power amplifier and the band-elimination filter.

7. The power amplifier circuit according to claim 1, wherein the first channel and the second channel are included in a same band.

8. The power amplifier circuit according to claim 7, wherein intra-band contiguous carrier aggregation (CA) is supported in the same band.

9. The power amplifier circuit according to claim 1, wherein the envelope tracking mode is applied to the power amplifier under a condition that one of the first signal or the second signal is transmitted.

10. The power amplifier circuit according to claim 1 further comprising:
a multimode tracker configured to selectively supply a power supply voltage in the envelope tracking mode and a power supply voltage in the average power tracking mode.

11. A radio frequency circuit comprising:
a power amplifier circuit that includes a power amplifier configured to amplify a first signal in a first channel and a second signal in a second channel; and
a tracking circuit configured to supply a power supply voltage to the power amplifier,
wherein under a condition that the first signal and the second signal are simultaneously transmitted,
(i) the tracking circuit is configured to supply the power supply voltage to the power amplifier in an envelope tracking mode, under a condition that a frequency gap between the first channel and the second channel is less than a first threshold width,
(ii) the tracking circuit is configured to supply the power supply voltage to the power amplifier in an average power tracking mode, under a condition that the frequency gap is at least the first threshold width, and
(iii) the power amplifier is configured to amplify the first signal and the second signal by using the power supply voltage supplied from the tracking circuit.

12. The radio frequency circuit according to claim 11, wherein
in (i), the tracking circuit is configured to:
supply the power supply voltage to the power amplifier in a second envelope tracking mode under a condition that the frequency gap is at least a second threshold width and less than the first threshold width; and
supply the power supply voltage to the power amplifier in a first envelope tracking mode under a condition that the frequency gap is less than the second threshold width, and
the power supply voltage supplied in the second envelope tracking mode is higher than the power supply voltage supplied in the first envelope tracking mode.

13. The radio frequency circuit according to claim 11, wherein
in (ii), the tracking circuit is configured to:
supply the power supply voltage to the power amplifier in a first average power tracking mode under a condition that the frequency gap is at least the first threshold width and less than a third threshold width; and
supply the power supply voltage to the power amplifier in a second average power tracking mode under a condition that the frequency gap is at least the third threshold width, and
the power supply voltage supplied in the second average power tracking mode is higher than the power supply voltage supplied in the first average power tracking mode.

14. The radio frequency circuit according to claim 11, wherein
the power amplifier circuit further includes a band-elimination filter connected to the power amplifier, and
the band-elimination filter has an attenuation band that includes the frequency gap.

15. The radio frequency circuit according to claim 14, wherein the attenuation band of the band-elimination filter is variable.

16. The radio frequency circuit according to claim 14, wherein the power amplifier circuit further includes a switch circuit connected between the power amplifier and the band-elimination filter.

17. The radio frequency circuit according to claim 11, wherein the first channel and the second channel are included in a same band.

18. The radio frequency circuit according to claim 17, wherein intra-band contiguous carrier aggregation (CA) is supported in the same band.

19. The radio frequency circuit according to claim 11, wherein under a condition that one of the first signal or the second signal is transmitted, the tracking circuit is configured to supply the power supply voltage to the power amplifier in the envelope tracking mode.

20. A radio frequency circuit comprising:
a power amplifier circuit that includes a power amplifier configured to amplify a first signal in a first channel and a second signal in a second channel;
a tracking circuit that includes an envelope tracking circuit and an average tracking circuit;
a radio frequency integrated circuit (RFIC) that supplies the first signal and the second signal; and
a switch circuit connected between the power amplifier and the tracking circuit,
wherein the switch circuit is configured to switch between the envelope tracking circuit and the average tracking circuit based on a signal from the RFIC.
